(19) United States
(12) Patent Application Publication
(10) Pub. No.: US 2026/0353811 A1
(43) Pub. Date: Nov. 5, 2026

(54) INTEGRATION OF BACKSIDE TRANSISTOR WITH RAIL VIA

(71) Applicant: INTERNATIONAL BUSINESS MACHINES CORPORATION, Armonk, NY (US)

(72) Inventors: Kamal Rudra, Albany, NY (US); Ruilong Xie, Niskayuna, NY (US); Takashi Ando, Eastchester, NY (US); Fabio Carta, Pleasantville, NY (US)

(21) Appl. No.: 19/194,950

(22) Filed: Apr. 30, 2025

(51) Int. Cl. H10D 87/00; H10D 30/01; H10D 30/47; H10D 30/67; H10D 62/80

(52) U.S. Cl. CPC H10D 87/00; H10D 30/017; H10D 30/031; H10D 30/481; H10D 30/6755; H10D 62/875; H10D 62/883

(57) ABSTRACT

Embodiments of present invention provide a semiconductor structure. The semiconductor structure includes a backside transistor underneath a set of frontside transistors and a gate contact in contact with the backside transistor. The backside transistor is embedded in a backside dielectric layer and includes a channel layer that is made of oxide or 2D based material; and a gate insulating layer on top of the channel layer. A method of forming the same is also provided.

### BACKGROUND

The present application relates to manufacturing of semiconductor integrated circuits. More particularly, it relates to method of integrating backside transistor with power via and the structure formed thereby.

As semiconductor industry moves towards smaller node, field-effect-transistors (FETs) are aggressively scaled to fit into reduced footprint or real estate. Transistors may also be placed in, at the frontside of substrate or device, back-end-of-line (BEOL) areas for various application purposes. However, as interconnect structures in the BEOL area become smaller and denser, placement and thus use of transistors in the BEOL area may become increasingly impractical due to the large areas or real estate spaces occupied by the transistors.

### SUMMARY

Embodiments of present invention provide a semiconductor structure. The structure includes a backside transistor underneath a set of frontside transistors, the backside transistor being embedded in a backside dielectric layer and including a channel layer of oxide or 2D based material; and a gate insulating layer on top of the channel layer, and a gate contact in contact with the backside transistor.

In one embodiment, the backside transistor further includes a gate metal on top of the gate insulating layer, the gate metal having a same lateral dimension as the gate insulating layer and in direct contact with the gate contact.

In another embodiment, the backside transistor includes the gate metal, the gate insulating layer, and the channel layer and is surrounded by an encapsulation layer, the encapsulation layer being made of a material different from a material of the backside dielectric layer.

According to one embodiment, the semiconductor structure further includes a first and a second backside source/drain contact in contact with a first end and a second end of the channel layer at a bottom surface thereof, the first backside source/drain contact being a backside contact via and the second backside source/drain contact being a backside contact metal.

According to another embodiment, the semiconductor structure further includes a rail via between a first and a second frontside transistor of the set of frontside transistors, the rail via being conductively connected to the second end of the channel layer through the backside contact metal and a conductive via and conductively connected to a source/drain region of the second frontside transistor through a frontside source/drain contact.

In one embodiment, the gate contact is a rail via between a first and a second frontside transistor of the set of frontside transistors, the gate contact extending vertically through a shallow-trench-isolation region between and below the first and the second frontside transistor.

In another embodiment, the channel layer of the backside transistor has a thickness ranging from about 2 nm to about 20 nm and a length ranging from about 20 nm to about 1 um, and wherein the length of the channel layer is larger than a gap between the first and the second frontside transistor.

In yet another embodiment, the gate contact is in direct contact with the gate insulating layer.

In a further embodiment, the oxide is selected from a group consisting of indium-gallium-zinc-oxide, doped/undoped indium-oxide, tungsten-oxide, and indium-tin-oxide; and the 2D material is selected from a group consisting of molybdenum disulfide, tungsten diselenide, and tungsten disulfide.

Embodiments of present invention further provide a method of forming a semiconductor structure. The method includes forming a first and a second frontside transistor on a substrate; forming a rail via between the first and the second frontside transistor, the rail via extending vertically into shallow-trench-isolation region of the substrate; removing at least a portion of the substrate to expose a bottom surface of the rail via; depositing a layer of conductive material on top of the bottom surface of the rail via; a layer of insulating material on top of the layer of conductive material; and a layer of channel material on top of the layer of insulating material; patterning the layer of conductive material, the layer of insulating material, and the layer of channel material into, respectively, a gate metal, a gate insulating layer, and a channel layer thereby forming a backside transistor; forming a first and a second backside source/drain contact in contact with a first and a second end of the channel layer at a bottom surface thereof.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of cross-sectional view of a semiconductor structure at a step of manufacturing thereof according to one embodiment of present invention;

FIG. 2 is a demonstrative illustration of cross-sectional view of a semiconductor structure at a step of manufacturing thereof, following the step illustrated in FIG. 1, according to one embodiment of present invention;

FIG. 3 is a demonstrative illustration of cross-sectional view of a semiconductor structure at a step of manufacturing thereof, following the step illustrated in FIG. 2, according to one embodiment of present invention;

FIG. 4 is a demonstrative illustration of cross-sectional view of a semiconductor structure at a step of manufacturing thereof, following the step illustrated in FIG. 3, according to one embodiment of present invention;

FIG. 5 is a demonstrative illustration of cross-sectional view of a semiconductor structure at a step of manufacturing thereof, following the step illustrated in FIG. 4, according to one embodiment of present invention;

FIG. 6 is a demonstrative illustration of cross-sectional view of a semiconductor structure at a step of manufacturing thereof, following the step illustrated in FIG. 5, according to one embodiment of present invention;

FIG. 7 is a demonstrative illustration of cross-sectional view of a semiconductor structure at a step of manufacturing thereof, following the step illustrated in FIG. 6, according to one embodiment of present invention;

FIG. 8 is a demonstrative illustration of cross-sectional view of a semiconductor structure at a step of manufacturing thereof, following the step illustrated in FIG. 7, according to one embodiment of present invention;

FIG. 9 is a demonstrative illustration of cross-sectional view of a semiconductor structure at a step of manufacturing thereof, following the step illustrated in FIG. 8, according to one embodiment of present invention;

FIG. 10 is a demonstrative illustration of cross-sectional view of a semiconductor structure at a step of manufacturing thereof, following the step illustrated in FIG. 9, according to one embodiment of present invention;

FIG. 11 is a demonstrative illustration of cross-sectional view of a semiconductor structure at a step of manufacturing thereof, following the step illustrated in FIG. 10, according to one embodiment of present invention;

FIG. 12 is a demonstrative illustration of cross-sectional view of a semiconductor structure according to another embodiment of present invention;

FIG. 13 is a demonstrative illustration of cross-sectional view of a semiconductor structure according to yet another embodiment of present invention;

FIG. 14 is a demonstrative illustration of cross-sectional view of a semiconductor structure according to yet another embodiment of present invention;

FIG. 15 is a demonstrative illustration of cross-sectional view of a semiconductor structure according to yet another embodiment of present invention;

FIG. 16 is a demonstrative illustration of cross-sectional view of a semiconductor structure according to yet another embodiment of present invention; and

FIG. 17 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

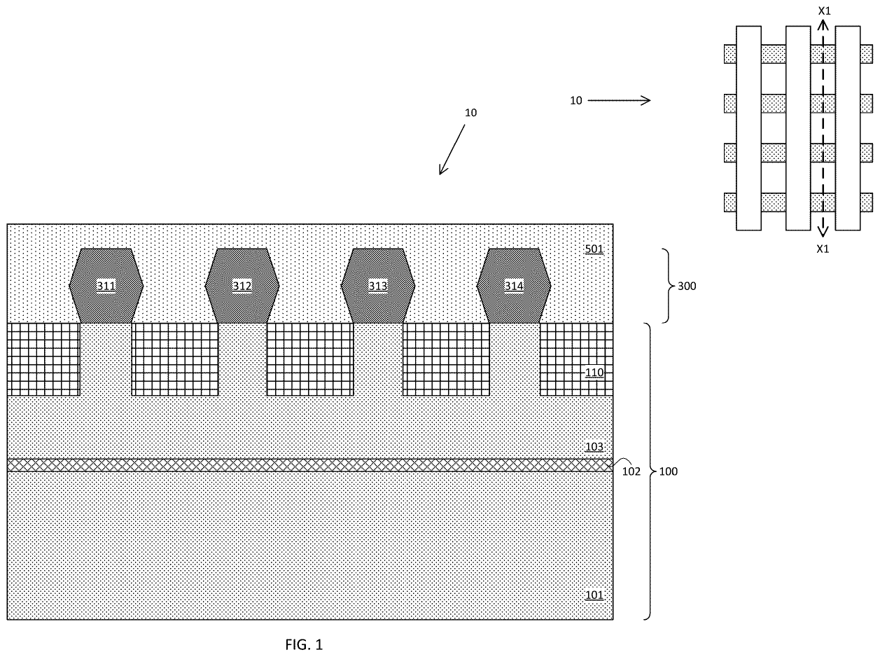

FIG. 1 is a demonstrative illustration of cross-sectional view of a semiconductor structure 10 at a step of manufacturing thereof according to one embodiment of present invention. More specifically, FIG. 1 illustrates a cross-sectional view of the semiconductor structure 10 with a cross-section made along a dashed line X1-X1 as indicated in the simplified top view of the semiconductor structure 10 at the up-right corner of the drawing. In other words, the cross-section is made across S/D regions of a set of transistors and in a direction along the width of gate of the set of transistors.

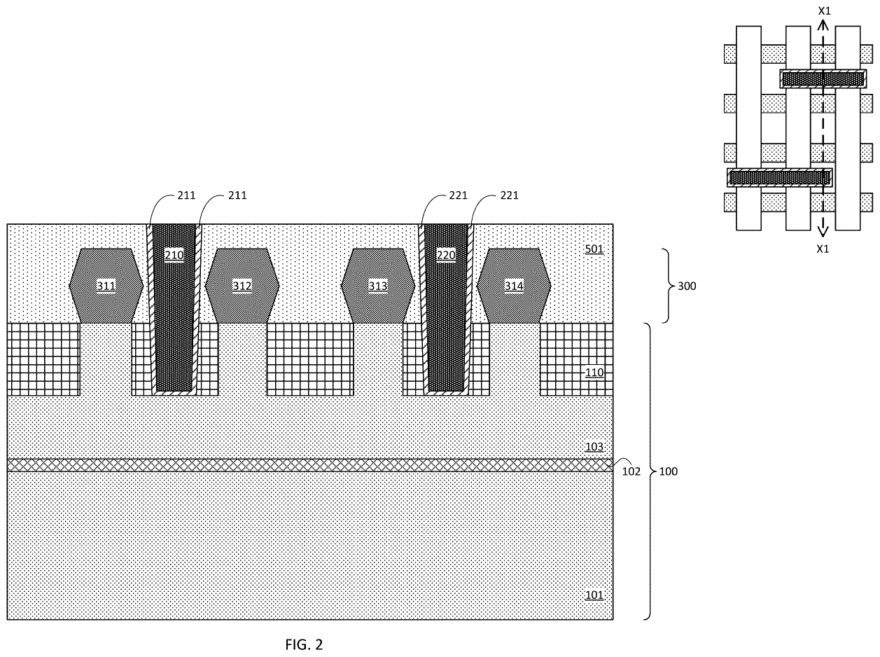

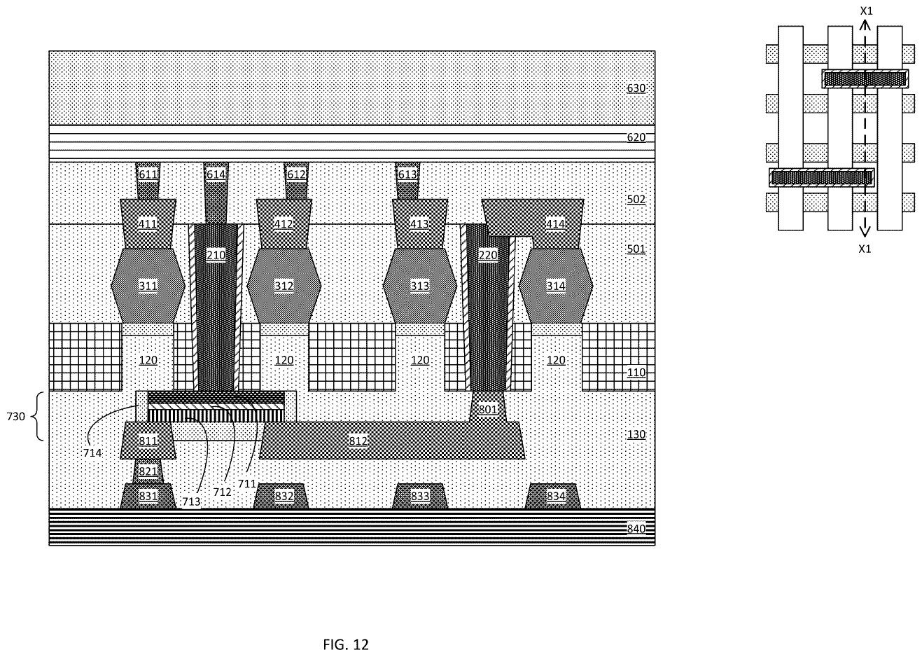

Likewise, FIG. 2 to FIG. 11 are demonstrative cross-sectional views of the semiconductor structure 10, at different manufacturing steps, and FIG. 12 to FIG. 15 are demonstrative cross-sectional views of various embodiments of semiconductor structures, all of which are illustrated in manners similar to FIG. 1.

Embodiments of present invention provide forming a semiconductor structure 10 that is demonstratively illustrated in FIG. 1 to include at least one set of transistors, although embodiments of present invention are not limited in this aspect and may be applied to other types of active devices as well. For example, the semiconductor structure 10 includes a semiconductor substrate 100 and a set of transistors on top thereof. Being formed on top of the semiconductor substrate 100, the set of transistors may be known or referred to as a set of frontside transistors 300.

The semiconductor substrate 100 may include a bulk silicon (Si) substrate 101, a dielectric layer 102 on top of the Si substrate 101, and a Si layer 103 on top of the dielectric layer 102. One or more shallow-trench-isolation (STI) regions 110 may be formed to be embedded in the Si layer 103. The dielectric layer 102 may be an insulating layer and may serve as an etch-stop-layer (ESL) during a subsequent processing step.

The set of frontside transistors 300 may be a set of nanosheet transistors to include multiple metal gates with each surrounding a set of nanosheets and source/drain regions adjacent to and separated from, respectively, the multiple metal gates. For example, the set of frontside transistors 300 may include a first, a second, a third, and a fourth source/drain region 311, 312, 313 and 314, as demonstratively illustrated in FIG. 1, that are epitaxially formed directly on top of the Si layer 103. The first, second, third, and fourth source/drain regions 311, 312, 313 and 314 may be insulated from each other, in the semiconductor substrate 100, by the one or more STI regions 110 and are surrounded by or embedded in a dielectric layer 501 on top of the semiconductor substrate 100. In one embodiment, the dielectric layer 501 may be an interlevel dielectric (ILD) layer.

FIG. 2 is a demonstrative illustration of cross-sectional view of a semiconductor structure at a step of manufacturing thereof, following the step illustrated in FIG. 1, according to one embodiment of present invention. More particularly, embodiments of present invention provide forming one or more rail vias between the set of frontside transistors 300 and into the semiconductor substrate 100 to reach the Si layer 103. For example, a first rail via (RV) 210 may be formed between the neighboring first and second source/drain regions 311 and 312. The first RV 210 may be formed by first creating a via opening, in a lithographic patterning and etching process, through the dielectric layer 501 and the STI regions 110. Next, a layer of dielectric material such as, for example, silicon-nitride (SiN), aluminum-oxide (AlO), aluminum-nitride (AlN) or other suitable material may be deposited in the via opening, preferably conformally, to form a dielectric insulating layer 211. Subsequently, a conductive material such as tungsten (W), copper (Cu), cobalt (Co), aluminum (Al) or other suitable material may be deposited on top of the dielectric insulating layer 211 to form the RV 210. The deposition of the dielectric insulating layer 211 and/or the RV 210 may be made by an atomic-layer-deposition (ALD) process, a chemical-vapor-deposition (CVD) process, a physical-vapor-deposition (PVD) process, or other currently existing or future developed processes.

Similarly, a second RV 220, surrounded by a dielectric insulating layer 221, may be formed between the neighboring third and fourth source/drain regions 313 and 314. The first and the second RV 210 and 220 extend downwardly into the semiconductor substrate 100, through the dielectric layer 501 and the STI regions 110, to reach the Si layer 103.

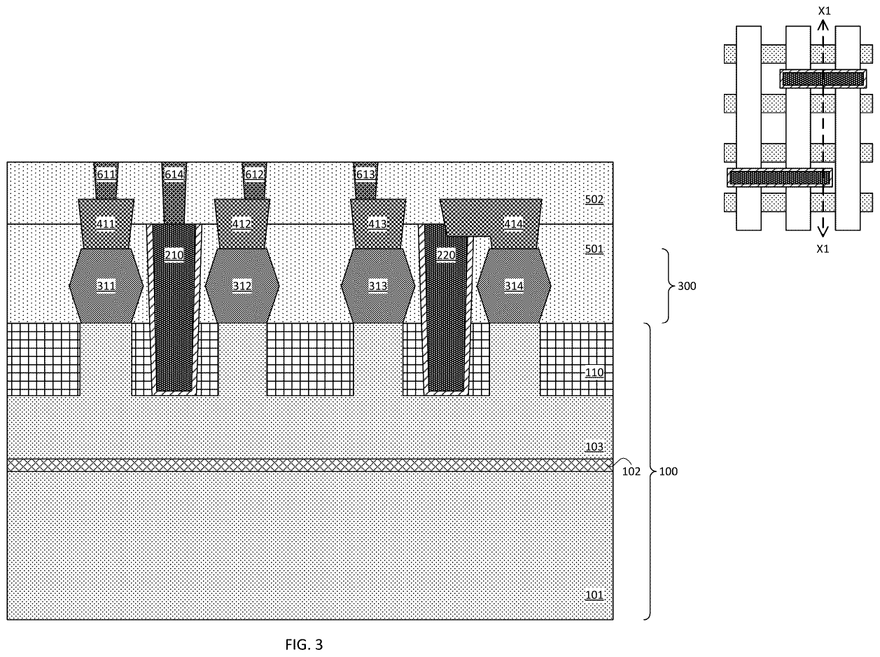

FIG. 3 is a demonstrative illustration of cross-sectional view of a semiconductor structure at a step of manufacturing thereof, following the step illustrated in FIG. 2, according to one embodiment of present invention. More particularly, embodiments of present invention provide forming middle-of-line (MOL) structures such as, for example, forming a first, a second, a third, and a fourth source/drain contact 411, 412, 413 and 414 in contact respectively with the first, the second, the third and the fourth source/drain region 31, 312, 313 and 314. In one embodiment, the fourth source/drain contact 414 is additionally in conductive contact with the second RV 220 as well.

Embodiments of present invention further provide forming one or more conductive vias such as conductive vias 611, 612 and 613 in contact with some of the source/drain contacts and a conductive via 614 in contact with the first RV 210. Additional dielectric material may be deposited on top of the structure forming a dielectric layer 502, such that the source/drain contacts 411, 412, 413 and 414 and/or conductive vias 611, 612, 613 and 614 are surrounded by or embedded in the dielectric layer 502 and/or the dielectric layer 501.

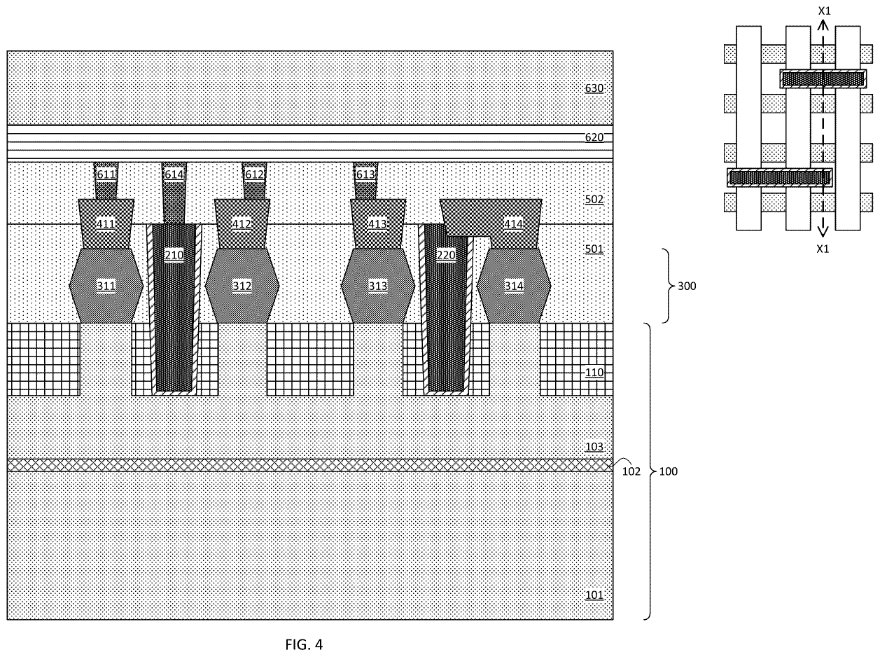

FIG. 4 is a demonstrative illustration of cross-sectional view of a semiconductor structure at a step of manufacturing thereof, following the step illustrated in FIG. 3, according to one embodiment of present invention. More particularly, embodiments of present invention provide forming a back-end-of-line (BEOL) structure 620 on top of the dielectric layer 502 and on top of the one or more conductive vias 611, 612, 613 and 614. A handling wafer or carrier wafer 630 is subsequently bonded onto the BEOL structure 620 such that the semiconductor structure 10 may be flipped upside down for further processing from a backside of the semiconductor substrate 100.

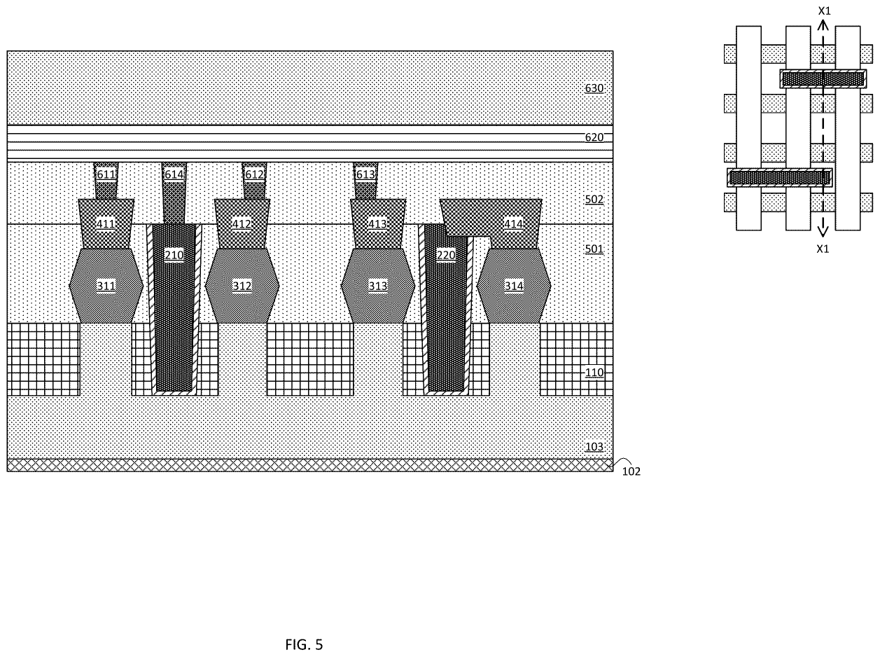

FIG. 5 is a demonstrative illustration of cross-sectional view of a semiconductor structure at a step of manufacturing thereof, following the step illustrated in FIG. 4, according to one embodiment of present invention. More particularly, continuing from the backside of the semiconductor substrate 100, embodiments of present invention provide selectively removing the Si substrate 101 through, for example, a grinding process, a CMP process, a selective etching process, or other suitable processes. For example, the Si substate may be substantially removed through a selective etch process, using the dielectric layer 102 as an etch-stop layer. In other words, when the dielectric layer 102 is exposed, the etch process may substantially slow down, facilitating the control of removal process of the Si substrate 101.

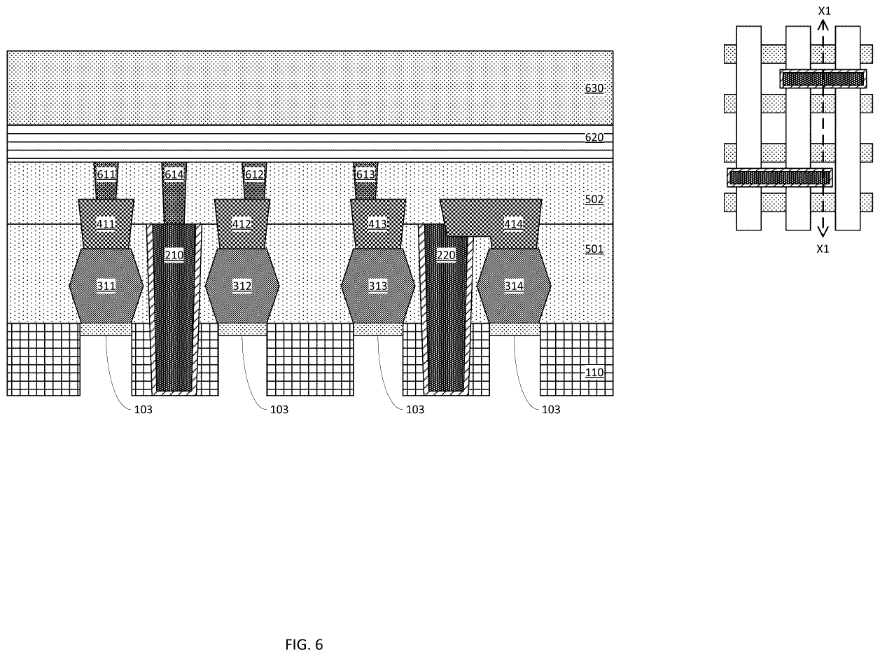

FIG. 6 is a demonstrative illustration of cross-sectional view of a semiconductor structure at a step of manufacturing thereof, following the step illustrated in FIG. 5, according to one embodiment of present invention. More particularly, embodiments of present invention provide continuing to remove the exposed dielectric layer 102, and subsequently a portion of the Si layer 103. More particularly, the Si layer 103 below the level of the one or more STI regions 110 may be removed, together with a portion of the Si layer 103 between the one or more STI regions 110 that are directly underneath the one or more source/drain regions 311, 312, 313 and 314. The remaining portion of the Si layer 103 may provide protection for the one or more epitaxial source/drain regions 311, 312, 313 and 314. However, embodiments of present invention are not limited in this aspect and in one embodiment, the Si layer 103 may be completely removed.

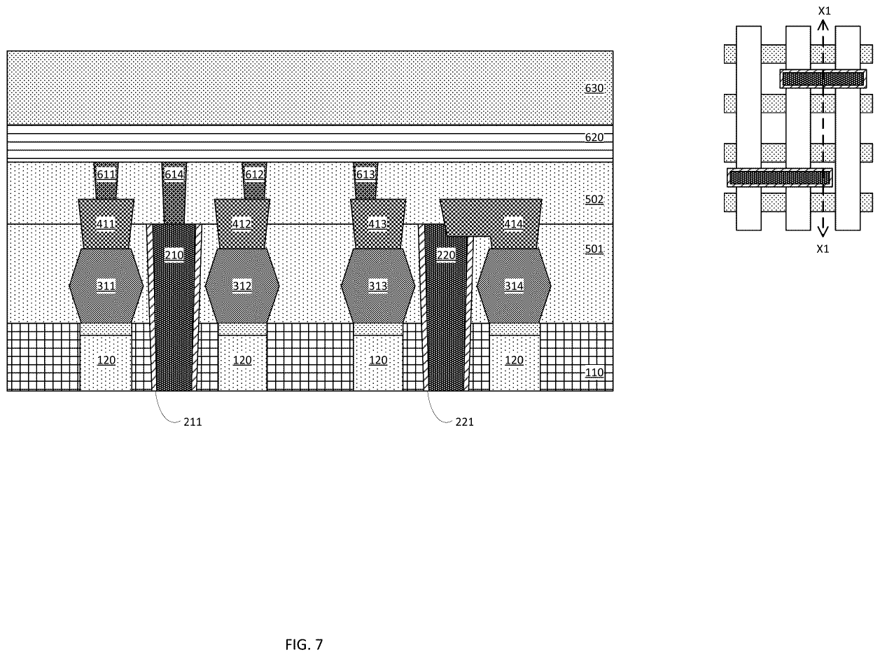

FIG. 7 is a demonstrative illustration of cross-sectional view of a semiconductor structure at a step of manufacturing thereof, following the step illustrated in FIG. 6, according to one embodiment of present invention. More particularly, embodiments of present invention provide filling the openings underneath the source/drain regions, created by the partial removal of the Si layer 103, with a dielectric material through a deposition process such as an ALD process, a CVD process, or a PVD process thereby forming one or more dielectric studs 120. A CMP process may subsequently be applied to planarize a top surface (shown in FIG. 7 as a bottom surface) of the dielectric studs 120. The CMP process may also remove a portion of the dielectric insulating layer 211 and expose bottom surfaces of the first and the second RV 210 and 220. In one embodiment, the first and the second RV 210 and 220, from the exposed bottom surfaces thereof, may be etched to create recesses and another type of conductive material, metal, or metal composite, which is different from that of the first and the second RV 210 and 220, may be deposited in the recesses. This conductive material, metal, or metal composite may be used to tune threshold of a backside transistor to be formed in contact with the RV 210, as being described below in more details.

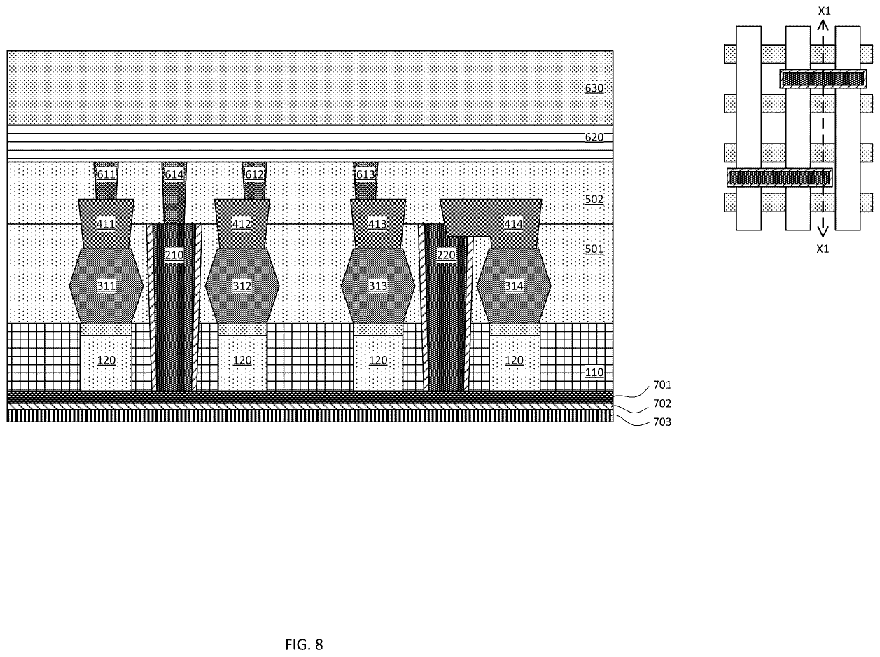

FIG. 8 is a demonstrative illustration of cross-sectional view of a semiconductor structure at a step of manufacturing thereof, following the step illustrated in FIG. 7, according to one embodiment of present invention. More particularly, embodiments of present invention provide depositing a conductive material layer 701 on top of and in contact with the first and the second RV 210 and 220, the STI regions 110, and the dielectric studs 120; depositing an insulating material layer 702 on top of the conductive material layer 701; and depositing a channel material layer 703 on top of the insulating material layer 702. In one embodiment, deposition of the conductive material layer 701 may be omitted and the insulating material layer 702 may be deposited directly on top of the first and the second RV 210 and 220.

In one embodiment, the conductive material layer 701 may be made of tungsten (W), copper (Cu), cobalt (Co), aluminum (Al), tungsten-nitride (WN), titanium-nitride (TiN), tantalum-nitride (TaN), or other suitable material with a thickness ranging from about 3 nm to about 300 nm. The insulating material layer 702 may be made of hafnium-oxide (HfOx), aluminum-oxide (AlOx), zirconium-oxide (ZrOx), silicon-oxide (SiOx), or a combination thereof in a multi-layer structure, with a thickness ranging from about 0.5 nm to about 5 nm. The channel material layer 703 may be made of some oxide materials such as, for example, indium-gallium-zinc-oxide (IGZO), doped/undoped indium-oxide (In₂O₃), tungsten-oxide (WO₃), and indium-tin-oxide (ITO). The channel material layer 703 may also be made of some 2D materials including but not limited to, for example, molybdenum disulfide (MoS₂), tungsten diselenide (WSe₂), tungsten disulfide (WS₂) with a thickness ranging from about 2 nm to about 20 nm. Other oxide and/or 2D materials may be used as channel materials. A 2D material generally refers to a material that has only one dimension that is nano-sized, resembling a large but very thin sheet such as a nanosheet. A 2D material may also refer to crystalline solids consisting of a single layer of atoms. Single-layer materials derived from single elements generally carry the -ene suffix in their names, e.g., graphene. Single-layer materials that are compounds of two or more elements have -ane or -ide suffixes such as those listed above. 2D materials can generally be categorized as either 2D allotropes of various elements or as compounds consisting of two or more covalently bonding elements.

Thicknesses of the various layers, including the conductive material layer 701, the insulating material layer 702, and the channel material layer 703, may be important as they affect the performance of a backside transistor to be subsequently made from. For example, thickness of the channel material may affect the flow of current, leak current, and the source-drain resistance of the backside transistor.

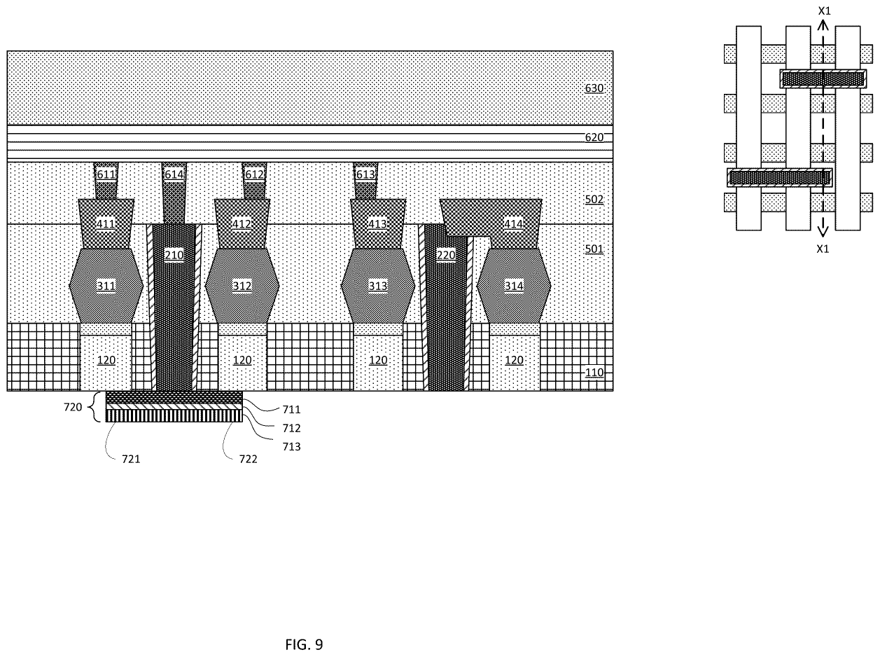

FIG. 9 is a demonstrative illustration of cross-sectional view of a semiconductor structure at a step of manufacturing thereof, following the step illustrated in FIG. 8, according to one embodiment of present invention. More particularly, embodiments of present invention provide applying a lithographic patterning to pattern the conductive material layer 701, the insulating material layer 702, and the channel material layer 703 into a backside transistor 720.

According to one embodiment, the backside transistor 720 may include a gate metal 711, a gate insulating layer 712, and a channel layer 713 that are respectively formed from the conductive material layer 701, the insulating material layer 702, and the channel material layer 703 through the patterning process. By the nature of the lithographic patterning process, the gate metal 711, the gate insulating layer 712, and the channel layer 713 may have a same or substantially same lateral dimension or length, as is illustrated in FIG. 9, to be the length of the backside transistor 720. In one embodiment, the length of the backside transistor 720 may range from about 20 nm to about 1 um (micrometer), and maybe larger or longer than a gap between the first and the second source/drain region 311 and 312 of the set of frontside transistors 300.

A first end of the backside transistor 720, such as a first end 721 of the channel layer 713, may be vertically underneath the first source/drain region 311 and a second end of the backside transistor 720, such as a second end 722 of the channel layer 713, may be vertically underneath the second source/drain region 312. The first end 721 of the channel layer 713 may be, or function as, a first source/drain region of the backside transistor 720 and the second end 722 of the channel layer 713 may be, or function as, a second source/drain region of the backside transistor 720.

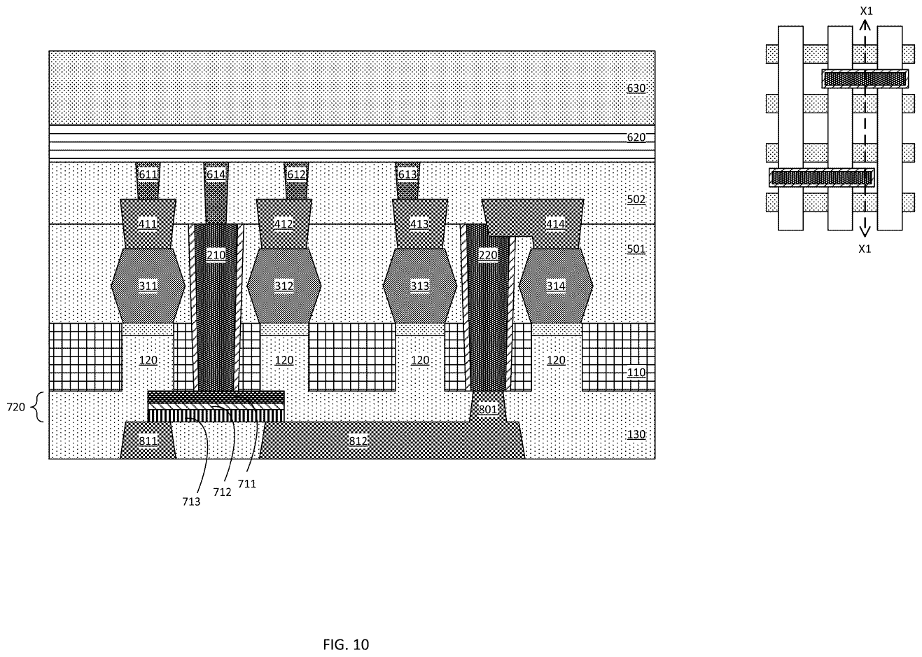

FIG. 10 is a demonstrative illustration of cross-sectional view of a semiconductor structure at a step of manufacturing thereof, following the step illustrated in FIG. 9, according to one embodiment of present invention. More particularly, embodiments of present invention provide depositing dielectric materials on top of the backside transistor 720, the dielectric studs 120 and the STI regions 110 to form a backside interlevel-dielectric (BILD) layer 130, such that the backside transistor 720 may be surrounded by or embedded in the BILD layer 130. In one embodiment, through a bottom surface of the channel layer, a backside contact via 811 may be formed to be in contact with the first end 721 of the channel layer 713, i.e., the first source/drain region of the backside transistor 720, and a backside contact metal 812 may be formed to be in contact with the second end 722 of the channel layer 713, i.e., the second source/drain region of the backside transistor 720. The backside contact metal 812 may be a metal line having a length significantly longer than a width. A conductive via 801 may also be formed to conductively connect the backside contact metal 812 with the second RV 220. As a result, the second end 722 of channel layer 713, i.e., the second source/drain region of the backside transistor 720 is conductively connected to the fourth source/drain region 314 of the set of frontside transistors 300.

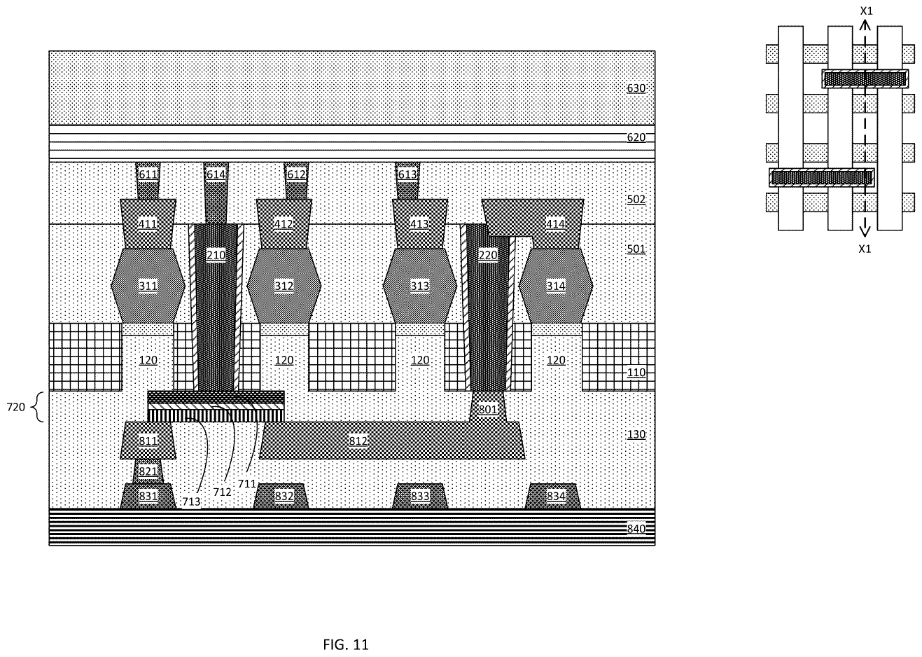

FIG. 11 is a demonstrative illustration of cross-sectional view of a semiconductor structure at a step of manufacturing thereof, following the step illustrated in FIG. 10, according to one embodiment of present invention. More particularly, embodiments of present invention provide depositing dielectric material on top of the backside contact via 811 and the backside contact metal 812 to further expand the BILD layer 130. One or more backside metal lines 831, 832, 833, and 834 may be formed inside the BILD layer 130, and in one embodiment one or more of the source/drain regions of the backside transistor 720 may be connected to the one or more backside metal lines 831, 832, 833, and 834. For example, the first source/drain region of the backside transistor 720, at the first end 721 of the channel layer 713, may be connected to the first backside metal line 831 through a conductive via 821.

Embodiments of present invention further provide forming a backside interconnect structure 840 on top of the BILD layer 130 to be conductively connected to the one or more backside metal lines 831, 832, 833, and 834. The backside interconnect structure 840 provides signal routing, power delivery functions to both the backside transistor 720 and one or more of the set of frontside transistors 300.

FIG. 12 is a demonstrative illustration of cross-sectional view of a semiconductor structure according to another embodiment of present invention. More particularly, embodiments of present invention provide a backside transistor 730 that is covered or surrounded, at least at sidewalls and a bottom thereof, by an encapsulation layer 714. The encapsulation layer 714 may be formed after the formation of the backside transistor 720, as is illustrated in FIG. 9, and may be made of a dielectric material different from that of the BILD layer 130. For example, the encapsulation layer 714 may be made of SiC, SiCN, or AiOx and the BILD layer 130 may be made of SiOx. The encapsulation layer 714 helps prevent possible drift of channel material of the backside transistor 730 and/or contamination of the channel material due to exposure to surrounding materials. Additionally, the encapsulation layer 714 may serve as an etch-stop-layer (ESL) during subsequent processing.

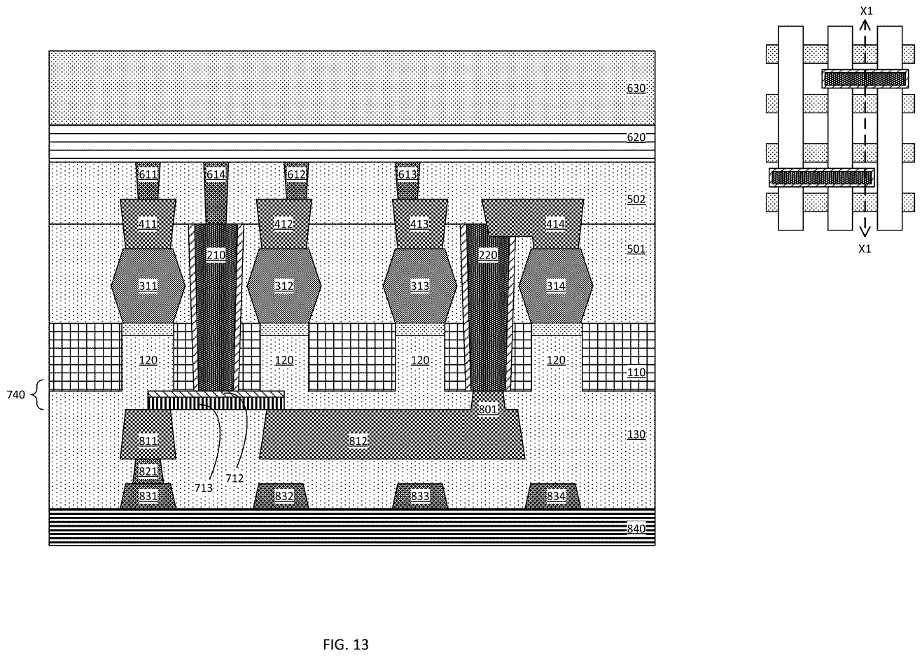

FIG. 13 is a demonstrative illustration of cross-sectional view of a semiconductor structure according to yet another embodiment of present invention. More particularly, embodiments of present invention provide a backside transistor 740 where the RV 210 is in direct contact with the gate insulating layer 712. In other words, the backside transistor 740 includes the gate insulating layer 712 and the channel layer 713, and uses a bottom portion of the RV 210, which is a conductive material such as metal, as a gate metal without the gate metal 711 as is illustrated in FIG. 9.

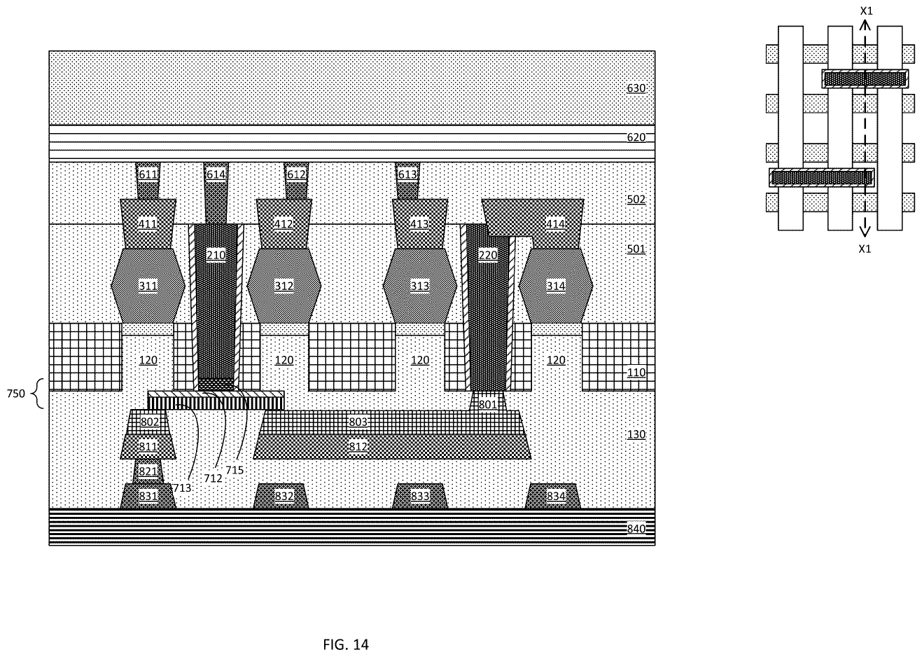

FIG. 14 is a demonstrative illustration of cross-sectional view of a semiconductor structure according to yet another embodiment of present invention. More particularly, embodiments of present invention provide a backside transistor 750, where the backside contact via and/or backside contact metal may include one or more types of conductive material. For example, on top of the backside contact via 811 of a first material such as W, Cu, or Al, there may be a second material 802 of, for example, InSnO (ITO), Al, or nickel (Ni). Similarly on top of the backside contact metal 812 of a first material such as W, Cu, or Al, there may be a second material 803 of ITO, Al, or Ni as well. The use of more than one type of conductive material helps forming ohmic or near-ohmic contact in reducing contact resistance.

In another embodiment, the RV 210 may include a bottom portion 715 of metal or metal composite different from that of rest of the RV 210. The metal or metal composite of the bottom portion 715 may be formed to fine tune threshold of the backside transistor 750. The bottom portion 715 may be formed through etching the RV 210 to create a recess and depositing material in the recess as being described above with reference to FIG. 7.

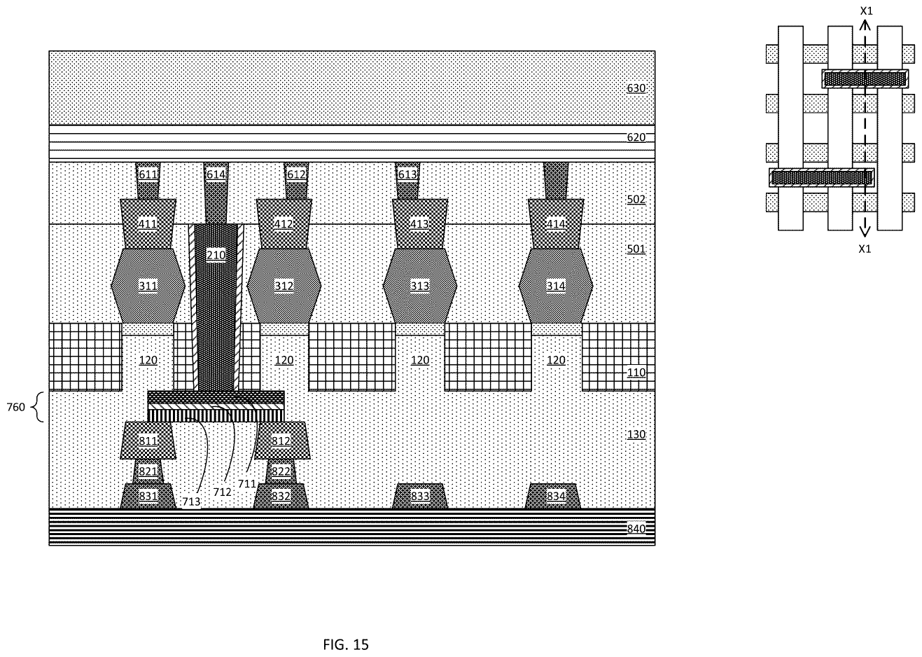

FIG. 15 is a demonstrative illustration of cross-sectional view of a semiconductor structure according to yet another embodiment of present invention. More particularly, embodiments of present invention provide a backside transistor 760, where both the first and the second source/drain region of the backside transistor 760 are connectively connected to backside metal lines such as the first and second backside metal lines 831 and 832, through conductive vias 821 and 822.

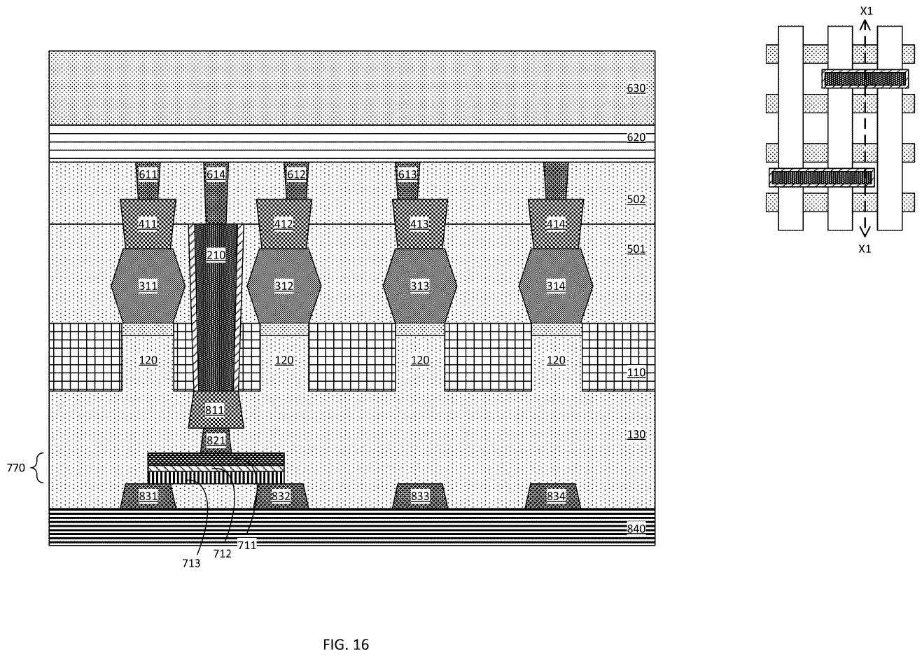

FIG. 16 is a demonstrative illustration of cross-sectional view of a semiconductor structure according to yet another embodiment of present invention. More particularly, embodiments of present invention provide a backside transistor 770, where the RV 210 is not in direct contact with the backside transistor 770, but rather is conductively connected to a gate of the backside transistor 770 through a backside contact via 811 and a conductive via 821.

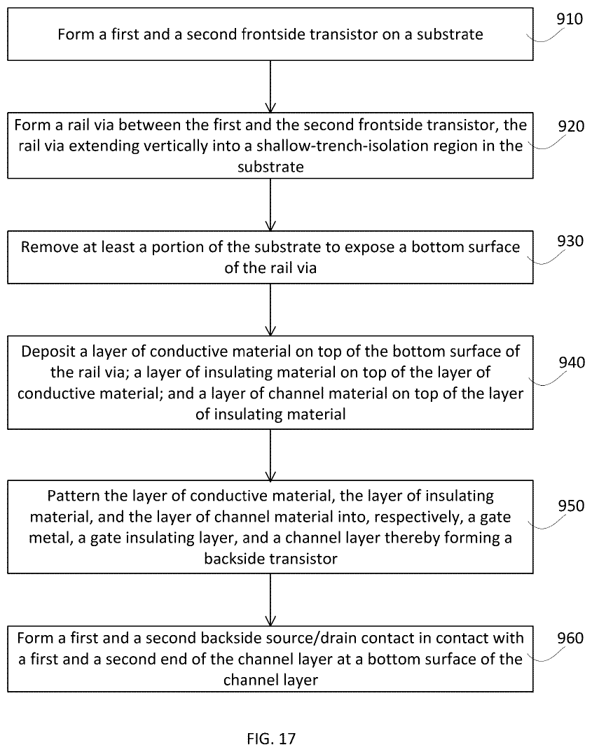

FIG. 17 is a demonstrative illustration of a flow-chart of a method of manufacturing a semiconductor structure according to embodiments of present invention. The method includes (910) forming a first and a second frontside transistor on a substrate; (920) forming a rail via between the first and the second frontside transistor, the rail via extending vertically into a shallow-trench-isolation region in the substrate; (930) removing at least a portion of the substrate to expose a bottom surface of the rail via; (940) depositing a layer of conductive material on top of the bottom surface of the rail via; a layer of insulating material on top of the layer of conductive material; and a layer of channel material on top of the layer of insulating material; (950) patterning the layer of conductive material, the layer of insulating material, and the layer of channel material into, respectively, a gate metal, a gate insulating layer, and a channel layer thereby forming a backside transistor; and (960) forming a first and a second backside source/drain contact in contact with a first and a second end of the channel layer at a bottom surface of the channel layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a backside transistor underneath a set of frontside transistors, the backside transistor being embedded in a backside dielectric layer and comprising:
a channel layer of oxide or 2D material; and
a gate insulating layer on top of the channel layer, and
a gate contact in contact with the backside transistor.

2. The semiconductor structure of claim 1, wherein the backside transistor further comprises a gate metal on top of the gate insulating layer, the gate metal having a same lateral dimension as the gate insulating layer and in direct contact with the gate contact.

3. The semiconductor structure of claim 2, wherein the backside transistor includes the gate metal, the gate insulating layer, and the channel layer and is surrounded by an encapsulation layer, the encapsulation layer being made of a material different from a material of the backside dielectric layer.

4. The semiconductor structure of claim 1, further comprising a first and a second backside source/drain contact in contact with a first end and a second end, respectively, of the channel layer at a bottom surface thereof, the first backside source/drain contact being a backside contact via and the second backside source/drain contact being a backside contact metal.

5. The semiconductor structure of claim 4, further comprising a rail via between a first and a second frontside transistor of the set of frontside transistors, the rail via being conductively connected to the second end of the channel layer through the backside contact metal and a conductive via and conductively connected to a source/drain region of the second frontside transistor through a frontside source/drain contact.

6. The semiconductor structure of claim 1, wherein the gate contact is a rail via between a first and a second frontside transistor of the set of frontside transistors, the gate contact extending vertically through a shallow-trench-isolation region between and below the first and the second frontside transistor.

7. The semiconductor structure of claim 6, wherein the channel layer of the backside transistor has a thickness ranging from about 2 nm to about 20 nm and a length ranging from about 20 nm to about 1 um, and wherein the length of the channel layer is larger than a gap between the first and the second frontside transistor.

8. The semiconductor structure of claim 1, wherein the gate contact is in direct contact with the gate insulating layer.

9. The semiconductor structure of claim 1, wherein the oxide is selected from a group consisting of indium-gallium-zinc-oxide, doped/undoped indium-oxide, tungsten-oxide, and indium-tin-oxide; and the 2D material is selected from a group consisting of molybdenum disulfide, tungsten diselenide, and tungsten disulfide.

10. A semiconductor structure comprising:
a backside transistor underneath a set of frontside transistors, the backside transistor being embedded in a backside dielectric layer and comprising:
a channel layer of oxide or 2D material;
a gate insulating layer on top of the channel layer; and
a gate metal on top of the gate insulating layer, and
a gate contact in contact with the gate metal of the backside transistor.

11. The semiconductor structure of claim 10, wherein the gate metal, the gate insulating layer, and the channel layer have a same lateral dimension that is larger than a gap between two neighboring frontside transistors of the set of frontside transistors.

12. The semiconductor structure of claim 11, wherein the backside transistor is surrounded by an encapsulation layer at sidewalls and a bottom surface thereof, the encapsulation layer being made of a material different from a material of the backside dielectric layer.

13. The semiconductor structure of claim 10, further comprising a first and a second backside source/drain contact in contact with a bottom surface of the channel layer, the first and/or the second backside source/drain contact being either a backside contact via or a backside contact metal.

14. The semiconductor structure of claim 13, the backside contact metal is conductively connected, through a rail via, to a frontside source/drain contact, the frontside source/drain contact being in contact with a source/drain region of a frontside transistor of the set of frontside transistors.

15. The semiconductor structure of claim 10, wherein the gate contact is a rail via between a first and a second frontside transistor of the set of frontside transistors, the gate contact extending vertically to a level below the first and the second frontside transistor to be in contact with the gate metal of the backside transistor.

16. The semiconductor structure of claim 10, wherein the channel layer is made of one or more of following materials: indium-gallium-zinc-oxide, doped/undoped indium-oxide, tungsten-oxide, indium-tin-oxide; molybdenum disulfide, tungsten diselenide, and tungsten disulfide.

17. A method of forming a semiconductor structure, the method comprising:
forming a first and a second frontside transistor on a substrate;
forming a rail via between the first and the second frontside transistor, the rail via extending vertically into shallow-trench-isolation region of the substrate;
removing at least a portion of the substrate to expose a bottom surface of the rail via;
depositing a layer of conductive material on top of the bottom surface of the rail via; a layer of insulating material on top of the layer of conductive material; and a layer of channel material on top of the layer of insulating material;
patterning the layer of conductive material, the layer of insulating material, and the layer of channel material into, respectively, a gate metal, a gate insulating layer, and a channel layer thereby forming a backside transistor; and
forming a first and a second backside source/drain contact in contact with a first and a second end of the channel layer at a bottom surface thereof.

18. The method of claim 17, wherein forming the first backside source/drain contact comprises forming a backside contact via in contact with the first end of the channel layer, and forming the second backside source/drain contact comprises forming a backside metal line in contact with the second end of the channel layer, the backside contact via and the backside metal line being part of a backside back-end-of-line structure.

19. The method of claim 17, further comprising forming an encapsulation layer surrounding sidewalls of the gate metal, the gate insulating layer, the channel layer and surrounding at least a portion of the bottom surface of the channel layer.

20. The method of claim 17, wherein the channel material is selected from a group consisting of indium-gallium-zinc-oxide, doped/undoped indium-oxide, tungsten-oxide, indium-tin-oxide; molybdenum disulfide, tungsten diselenide, and tungsten disulfide.
